(19) United States
(12) Patent Application Publication
(10) Pub. No.: US 2026/0153534 A1
(43) Pub. Date: Jun. 4, 2026

(54) APPARATUS AND A METHOD FOR TESTING AN ELECTRONIC DEVICE

(71) Applicant: JCET STATS ChipPAC Korea Limited, Incheon (KR)

(72) Inventors: MyungKi KIM, Incheon (KR); DongMin KIM, Gyeonggi-do (KR); SeokJin LEE, Gyeonggi-do (KR); DongWook KIM, Incheon (KR)

(21) Appl. No.: 19/407,036

(22) Filed: Dec. 3, 2025

(30) Foreign Application Priority Data
Dec. 4, 2024 (CN) 202411772655.0

(51) Int. Cl. G01R 1/04; G01R 31/28

(52) U.S. Cl. CPC G01R 1/0466; G01R 31/2863

(57) ABSTRACT

An apparatus and a method for testing an electronic device are provided. The apparatus comprises: a socket board having a device placement region, a test region, and a signaling route extending between a device contact pad and a socket board pad; a lower socket unit mounted on the device placement region, wherein the lower socket comprises a plurality of contact pins including a target contact pin aligned with the device contact pad; a calibration board removably mounted on the lower socket unit, wherein the calibration board comprises a test trace extending between a test pad and a connection pad electrically connectable with the target contact pin, such that a measurement result is generated by measuring an electrical characteristic associated with a testing path between the test pad and the socket board pad; and an upper socket unit mounted on the lower socket unit.

### TECHNICAL FIELD

The present application relates generally to semiconductor technology, and more particularly, to an apparatus and a method for testing an electronic device.

### BACKGROUND OF THE INVENTION

The semiconductor industry is constantly faced with complex integration challenges as consumers want their electronics to be smaller, faster and higher performance with more and more functionalities packed into a single device. Electronic devices that have undergone complicated processing are subjected to various types of electrical tests for testing their characteristics and for identifying their potential defects.

To this end, a test socket is used to electrically connect metallic wires or contact pads of a socket board (for example, a printed circuit board) mounted in test equipment with connectors or terminals of an electronic device to be tested. That is, when an electronic device is being tested, the test socket serves as an interface to electrically connect the socket board of the test equipment with the electronic device under test. Establishing the connection between the test equipment and the electronic device under test may induce a path loss that results in deterioration of the device performance, especially when the electronic device is tested at a high frequency. Thus, the path loss should be calibrated from test results of the electronic device to remove the deterioration of the device performance that occurs during the testing process, and improve accuracy of the test results. However, it is difficult to measure the path loss induced by the test socket and the socket board accurately by using existing test apparatuses.

Therefore, a need exists for an apparatus and a method for testing an electronic device.

### SUMMARY OF THE INVENTION

An objective of the present application is to provide an apparatus and a method for testing an electronic device to measure a path loss induced into a test result of the electronic device.

According to an aspect of the present application, an apparatus for testing an electronic device is provided. The apparatus comprises: a socket board having a device placement region, a test region, and a signaling route extending between a device contact pad in the device placement region and a socket board pad in the test region; a lower socket unit mounted on the device placement region, wherein the lower socket unit comprises a lower socket body, and a plurality of contact pins vertically extending through the lower socket body and movable vertically relative to the lower socket body, and wherein the plurality of contact pins comprises a target contact pin aligned with the device contact pad; a calibration board removably mounted on the lower socket unit, wherein the calibration board comprises a test trace extending between a test pad and a connection pad electrically connectable with the target contact pin when the calibration board is mounted on the lower socket unit, such that a measurement result is generated by measuring an electrical characteristic associated with a testing path between the test pad and the socket board pad which are electrically coupled with each other through the target contact pin; and an upper socket unit mounted on the lower socket unit, and for securing the calibration board with the lower socket unit.

According to another aspect of the present application, an apparatus for testing an electronic device is provided. The apparatus comprises: a socket board having a device placement region, a test region, and a signaling route extending between a device contact pad in the device placement region and a socket board pad in the test region; a lower socket unit mounted on the device placement region, wherein the lower socket unit comprises a lower socket body and a plurality of contact pins vertically extending through the lower socket body and movable vertically relative to the lower socket body, and the plurality of contact pins comprise a target contact pin aligned with the device contact pad; an upper socket unit operably mounted on the lower socket unit and having a cavity for accommodating the electronic device; a calibration board removably mounted between the lower socket unit and the upper socket unit when the apparatus is operating in the calibration mode, wherein the calibration board comprises a test trace extending between a test pad and a connection pad electrically connectable with the target contact pin when the calibration board is mounted on the lower socket unit, such that a measurement result is generated by measuring an electrical characteristic associated with a testing path between the test pad and the socket board pad which are electrically coupled with each other through the target contact pin; and a device socket lid removably mounted on the upper socket unit and insertable into the cavity of the upper socket unit and on the electronic device when the apparatus is operating in the test mode, and for pressing the plurality of contact pins against the socket board via the electronic device when the apparatus is operating in the test mode, such that the electronic device is electrically connected with the socket board through the contact pins and the electronic device is testable via the signaling route of the socket board.

In another aspect of the present application, a method for testing an electronic device using a test apparatus is provided. The test apparatus comprises: a socket board having a device placement region, a test region, and a signaling route extending between a device contact pad in the device placement region and a socket board pad in the test region. The method comprises: mounting a lower socket unit having a lower socket body and a plurality of contact pins vertically extending through the lower socket body and movable vertically relative to the lower socket body onto the device placement region of the socket board, to align a target contact pin of the plurality of contact pins with the device contact pad; mounting the calibration board having a test trace extending between a test pad and a connection pad onto the lower socket unit, to electrically connect the connection pad with the target contact pin; disposing an upper socket unit having a cavity onto the calibration board to fix the calibration board on the lower socket unit; generating a measurement result by measuring an electrical characteristic associated with the testing path between the test pad and the socket board pad which are electrically coupled with each other through the target contact pin; removing the calibration board from the lower socket unit and the upper socket unit; mounting the electronic device within the cavity of the upper socket unit to align a plurality of conductive pads of the electronic device with the plurality of contact pins, respectively; placing a device socket lid on the upper socket unit to insert a portion of the device socket lid into the cavity of the upper socket unit and onto the electronic device, to press the plurality of contact pins against the socket board via the electronic device and set up an electrical connection between the electronic device and the socket board through the contact pins; and testing the electronic device and calibrating a test result of the electronic device according to the measurement result.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1D illustrate an apparatus for testing an electronic device according to a first embodiment of the present application.

FIGS. 2A to 2H illustrate various steps of a method for testing an electronic device according to a second embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, when an electronic device is being tested by a test apparatus including a test socket and a socket board, a path loss may be inevitably induced into test results generated by the test apparatus. To be more specific, the test socket may include pogo pins which help establish electrical connections between the electronic device and the socket board to test the electronic device. During this testing process, the path losses of the pogo pins and other components in signaling paths may inevitably occur and be incorporated within a test result of the electronic device. Therefore, it is desired to calibrate or remove the path loss from the test result, so as to improve accuracy of the test result of the electronic device. However, it is difficult to accurately and conveniently measure path losses using conventional test apparatuses.

Some solutions have been provided to measure path losses of pogo pins. For example, a simulation of the path loss, or a pre-measured result of the path loss provided by pogo pin vendors may be used for calibration of a test result of an electronic device under test, instead of an actual measurement of the path loss when the electronic device is being tested. However, since this calibration information which is generated or measured beforehand is obtained in environments different from an actual testing environment of the electronic device, the accuracy of the calibration information of the path loss may still be unsatisfactory. In addition, when the path loss is measured beforehand, probes are generally used for connecting the pogo pins to measure the path losses. However, this measuring process may suffer from several issues such as poor contact reliability and deficient probe durability.

To address the above issues, an apparatus and a method for testing an electronic device are provided. The apparatus includes a socket board, a lower socket unit including a plurality of contact pins, a calibration board having a test trace extending between a test pad and a connection pad, and an upper socket unit. The apparatus is operable between a test mode and a calibration mode. W

hen the apparatus is operating in the calibration mode, the calibration board is mounted between the lower socket unit and the upper socket unit to electrically connect the connection pad with a target contact pin of the plurality of contact pins. Then a measurement result is generated by measuring an electrical characteristic associated with a testing path between the test pad and a socket board pad within the socket board and passing through the target contact pin. The measurement result may then be used for calibrating a test result of the electronic device using the same lower socket unit, upper socket unit and socket board. When the apparatus is operating in the test mode, a device socket lid is used to press the contact pins against the socket board via the electronic device to set up an electrical connection between the electronic device and the socket board to test the electronic device. During the process of generating the measurement result for calibration, the calibration board is used to provide a reliable connection from the target contact pin to test equipment, which allows for a convenient and accurate measurement of the electrical characteristic, such as path loss, associated with the testing path. In addition, by using the calibration board, an environment for calibration can be generated which mimics the actual testing environment where the electronic device is being tested, thereby resulting in a more reliable test result of the electronic device.

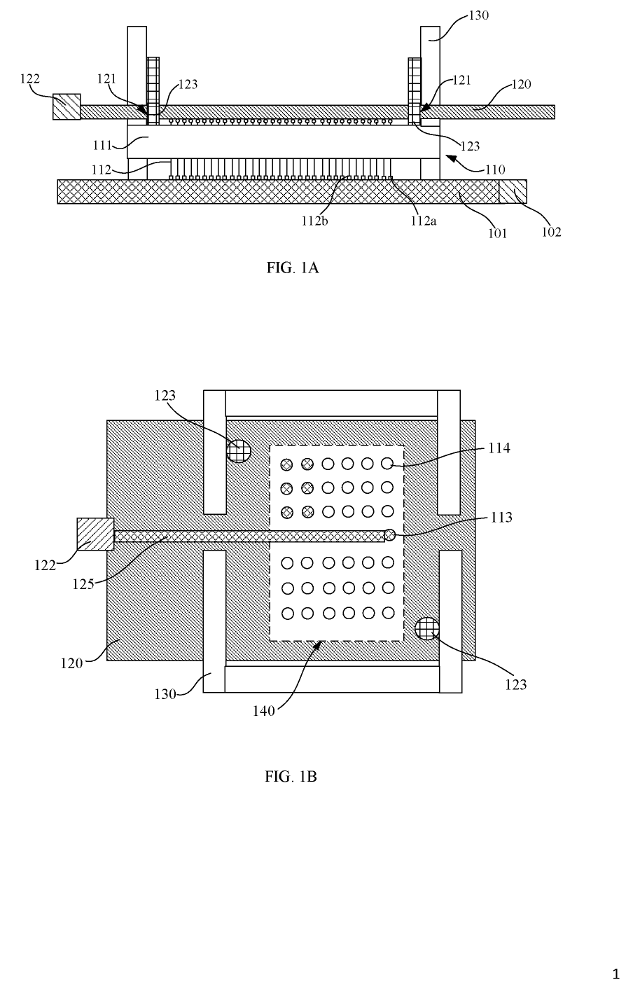

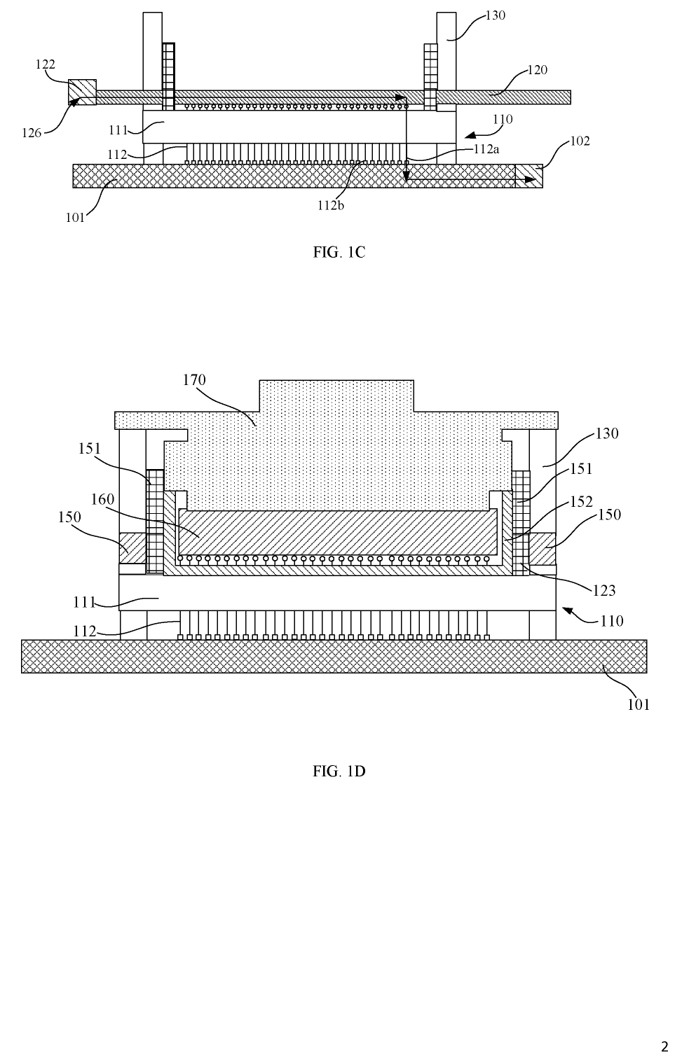

FIGS. 1A to 1D illustrate an apparatus for testing an electronic device according to a first embodiment of the present application. The apparatus can operate in a test mode under which a test result of the electronic device can be generated, and in another calibration mode under which calibration information for the test result can be generated.

Here, FIGS. 1A to 1C illustrate the calibration mode and certain parts of the apparatus for generating a measurement result for calibrating a test result of an electronic device. In particular, FIG. 1A illustrates a sectional view of a socket board, a lower socket unit, an upper socket unit and a calibration board of the apparatus. FIG. 1B illustrates a top view of the lower socket unit, the upper socket unit and the calibration board of the apparatus shown in FIG. 1A. FIG. 1C illustrates a testing path within the apparatus shown in FIG. 1A when it operates in the calibration mode to generate the measurement result. FIG. 1D illustrates a sectional view of the apparatus when it operates in the test mode for testing the electronic device, including the socket board, the lower socket unit, the upper socket unit shown in FIGS. 1A and 1B, and a device socket lid.

As shown in FIG. 1A, the apparatus includes a socket board 101 which serves as a base of the apparatus. The socket board 101 can be electrically connected with an electronic device when it is being tested. Also, the socket board 101 is electrically coupled to test equipment such as a multimeter with or without a signal generator for testing the electronic device. In some embodiments, the socket board 101 includes a device placement region for placing a testing fixture (e.g., a test socket) and the electronic device under test. Furthermore, the socket board 101 includes a test region where a test tool can be placed and/or connected such that the test tool can be electrically coupled with the electronic device to collect a measurement of the electronic device before or during a testing process of the electronic device. In some embodiments, the device placement region may be a central zone of the socket board 101, and the test region may be a peripheral zone of the socket board 101. Alternatively, the test region may be at a back side of the socket board 101 as long as it is convenient for the test tool to get access to. Furthermore, the socket board 101 includes a device contact pad in the device placement region and a socket board pad 102 in the test region of the socket board 101. A signaling route such as a metallic wire extends between a pair of the device contact pad and the socket board pad 102, which is used for transmitting signals between the electronic device and test equipment. For example, during the testing of the electronic device, the signaling route may be coupled with the signal generator of the test equipment to receive and apply to the electronic device a test signal. In some embodiments, the signaling route may have a respective layout corresponding to a layout of the electronic device, for example, a specific length corresponding to a size of the electronic device. Also, the device contact pad may be formed at a specific position of the socket board 101, which indicates the specific position of the signaling route corresponding to the layout of the electronic device.

Still referring to FIG. 1A, the apparatus includes a lower socket unit 110 and an upper socket unit 130 operably mounted on the device placement region of the socket board 101. During the testing process, the lower socket unit 110 and an upper socket unit 130 work together as a test socket assembly to accommodate the electronic device therewithin, and at the same time, provide an electrical connection between the electronic device and the socket board 101. This builds a test environment or system to test the electronic device. To be more specific, the lower socket unit 110 includes a lower socket body 111. The upper socket unit 130 is disposed above the lower socket body 111 and is aligned with the lower socket body 111. In some embodiments, both of the lower socket body 111 and the upper socket unit 130 may respectively include a vertical part extending perpendicular to the socket board 101. When viewed from its topside, the upper socket unit 130 may have a layout of a rectangular ring having an opening at its center, as shown in FIG. 1B. In particular, in some embodiments, the rectangular ring shaped upper socket unit 130 may be assembled by two half pieces which are arranged oppositely towards each other. It can be appreciated that the rectangular ring shaped upper socket unit 130 may alternatively be formed as an integral piece. Similarly, the vertical part of the lower socket body 111 may also have a layout of a rectangular ring, which can be vertically aligned with the vertical part of the upper socket unit 130. It can be appreciated that the vertical parts of the lower socket body 111 and the upper socket unit 130 may have the same layout or different layouts. Still referring to FIG. 1A, the lower socket body 111 may also include a horizontal part or platform extending between two opposite sides of the vertical part at a substantially middle level of the vertical part. The lower socket body 111 and the upper socket unit 130 together form an “H” shape when viewed from a section of a side of the apparatus. In this case, the electronic device may be disposed on the horizontal part for testing, as will be elaborated later.

Furthermore, the lower socket body 111 may have a plurality of through holes extending from its front surface to its back surface. Moreover, the lower socket unit 110 includes a plurality of contact pins 112 vertically extending through the lower socket body 111 and accommodated within the plurality of through holes, respectively. The contact pins 112 are movable vertically relative to the lower socket body 111. During the testing process of the electronic device, the contact pins 112 establish an elastic and electrical connection between the electronic device and the socket board 101. Top portions and bottom portions of the contact pins 112 may be exposed from the front surface and the bottom surface of the lower socket body 111 respectively to allow for convenient connections with the electronic device and the socket board 101. A region on the socket board 101 used for placement of the electronic device is shown as a dotted region 140 in FIG. 1B. It should be noted that the structure of the calibration board 120 above the region 140 is omitted for clarification in FIG. 1B, which only shows the respective pads thereon for connection with the contact pins 112.

Still referring to FIG. 1A, the contact pins 112 include a target contact pin 112a, which is aligned with the device contact pad and is electrically coupled with a signaling route during the testing of the electronic device. Apart from the target contact pin 112a, the contact pins 112 also include at least one non-target contact pin 112b which may not be electrically coupled with the signaling route. The at least one non-target contact pin 112b may be used for other purposes such as powering, grounding or connection with other signaling routes (e.g., non-target signaling routes). The socket board 101 may include at least one additional device contact pad in the device placement region which is used for coupling the at least one non-target contact pin 112b. The non-target contact pin 112b and the target contact pin 112a may have the same structure. In some embodiments, the contact pins 112 include pogo pins. Each pogo pin 112 includes a pipe-shaped pin body, a metallic top contactor coupled to a top end of the pin body, a metallic bottom contactor coupled to a bottom end of the pin body, and a compressible coil spring disposed inside the pin body. The compressible coil spring can be in contact with the top contactor at its top end, and can be in contact with the bottom contactor at its bottom end. As such, the pogo pins 112 can be movable vertically relative to the lower socket body 111 with the coil spring providing an elastic connection between the electronic device and the socket board 101. With these configurations, when the electronic device is being tested, the top contactors of the pogo pins 112 can be in contact with conductive pads of the electronic device, and the bottom contactors can be in contact with the device contact pad and the addition device contact pad in the device placement region. Additionally, the top contactors and the bottom contactors are exposed from the front surface and the back surface of the lower socket body 111. When the electronic device is being tested, the contact pins 112 may be pressed against the socket board 101 to set up a reliable electrical connection between the electronic device and the socket board 101, which builds a test environment or system to test the electronic device. In some other embodiments, the contact pins 112 may include other types of elastic connectors, such as elastic conductive pillars.

As shown in FIG. 1A in conjunction with FIG. 1B, a calibration board 120 used for generating calibration information is removably mounted between the lower socket unit 110 and the upper socket unit 130. In some embodiments, the calibration board 120 may be a printed circuit board with specially designed electrical patterns thereon. Referring to FIG. 1B, the calibration board 120 has a test trace 125 extending between a test pad 122 and a connection pad 113. In some embodiments, the test trace 125 may be a radio frequency (RF) trace. The RF trace is a conductive path designed to transmit high-frequency (RF) signals, which is typically used to route signals to a desired location or to measure impedance. When the calibration board 120 is mounted onto the lower socket unit 110, the connection pad 113 of the calibration board 120 is aligned with the target contact pin 112a. At the same time, the at least one non-target contact pins 112b may be aligned with additional conductive pads 114 on the calibration board 120, respectively. As such, the connection pad 113 is electrically connected with the target contact pin 112a, and the target contact pin 112a is electrically connected with the device contact pad and the signaling route within the socket board 101. This forms a testing path between the test pad 122 and the socket board pad 102 which are electrically coupled with each other.

An illustration of the testing path 126 is shown in FIG. 1C. As shown in FIGS. 1B and 1C, the testing path 126 extends from the test pad 122 of the calibration board 120, passes through the test trace 125 and the target contact pin 112a, and goes through the signaling route on the socket board 101 and finally reaches the socket board pad 102. An electrical characteristic associated with the testing path 126 may be measured between the test pad 122 and the socket board pad 102 to generate a measurement result for calibration. In some embodiments, the electrical characteristic associated with the testing path 126 between the test pad 122 and the socket board pad 102 may be measured using measurement equipment. The measurement equipment may be electrically coupled with the test pad 122 and the socket board pad 102. For example, the measurement equipment may be a VNA (Vector Network Analyzer). The test pad 122 may be connected with a first VNA port, for example, through a connector. The socket board pad 102 may be connected with a second VNA port, for example, through a connector. During the measurement of the electrical characteristic, the VNA may transmit a signal to the test pad 122 through the first VNA port. The signal may go through the testing path 126, and then may be received at the socket board pad 102 with a certain magnitude. The electrical characteristic may be calculated based on the input signal transmitted at the test pad 122 and the output signal received at the socket board pad 102.

In some embodiments, the electrical characteristic may be a path loss within the apparatus. To be more specific, the path loss may be an impedance of the testing path 126 which is measured between the test pad 122 and the socket board pad 102 by the measurement equipment, for example. In some embodiments, the test trace 125 is designed with a fixed impedance at a certain frequency, for example, based on a specific calibration algorithm. The electrical characteristic of the test trace 125 may be measured by the measurement equipment (e.g., VNA) separately from the measurement of the testing path 126 (e.g., before the measurement of the testing path 126). In some preferred embodiments, the test trace 125 may be maintained at 50 ohms when the path loss is being measured at the certain frequency. The fixed impedance of the test trace 125 can be removed from the measurement result of the testing path 126 (e.g., an impedance of the testing path 126) to achieve a path loss of the target contact pin 112a, the signaling route and the socket board pad 102 within the socket board 101, which can be used for calibration when the electronic device is being tested. In some embodiments, the test trace 125 may be designed to minimize the path loss at a frequency up to 10GHz.

In this embodiment, since the target contact pin 112a is connected with the test pad 122 via the test trace 125 and the connection pad 113, it is easy to get access to the target contact pin 112a from the test pad 122 and through the test trace 125, rather than a direct contact with the target contact pin 112a via probes, for example, in a conventional measuring configuration. As such, the calibration board 120 with the test trace 125 provides a reliable and stable connection from the target contact pin 112a to the measuring equipment, which allows for a convenient and accurate measurement of the path loss associated with the testing path 126. Also, the measurement may be carried out without repeated manual operations, which greatly saves cost and improves efficiency. In this way, the calibration information, such as the path loss including the target contact pin 112a can be accurately measured for calibrating a test result of the electronic device. In some preferred embodiments, a size of the calibration board 120 may be larger than that of the upper socket unit 130. In this case, the test trace 125 extends from an interior to an exterior of the upper socket unit 130, thereby the test pad 122 of the test trace 125 can be connected with the external measuring equipment more conveniently, which further improves contact reliability and convenience between the measuring equipment and the target contact pin 112a.

Furthermore, referring back to FIGS. 1A and 1B, the lower socket unit 110 may include a plurality of fixing pins 123 protruding from its top surface. Accordingly, the calibration board 120 further includes a plurality of through holes 121 for receiving the plurality of fixing pins 123 respectively when the calibration board 120 is mounted onto the lower socket unit 110. As such, the calibration board 120 can be accurately positioned relative to the lower socket unit 110, so as to align the connection pad 113 of the calibration board 120 with the target contact pin 112a. In addition, the calibration board 120 can be secured in place between the upper socket unit 130 and the lower socket unit 110 by the fixing pins 123 without undesired lateral movement. In some embodiments, the fixing pins 123 are arranged near a periphery of the lower socket unit 110. In some other embodiments, the fixing pins 123 may have a sufficient height such that an inner surface of the upper socket unit 130 may be adjacent to outer surfaces of the fixing pins 123. The number of the fixing pins 123 may be two, which are arranged diagonally with respect to the upper socket unit 130, thus securing the upper socket unit 130 in place. It can be appreciated that the number of the fixing pins 123 may be three, four or even more to fix the calibration board 120 in place in a more balanced manner.

In some embodiments, when the upper socket unit 130 is placed on the calibration board 120, the contact pins 112, including the target contact pin 112a and the at least one non-target contact pin 112b, may be pressed against the socket board 101 due to weights of the upper socket unit 130 and the calibration board 120. This further provides an improved accuracy of the measurement result for calibration since the apparatus creates a measurement environment that exactly mimics the actual testing environment where the electronic device is being tested. In some other embodiments, an additional pusher may be disposed on the upper socket unit 130 to press the calibration board 120 against the socket board 101. In some alternative embodiments, a fastener may be applied between the upper socket unit 130 and the lower socket unit 110 to further secure the calibration board 120 inside the apparatus and to press the calibration board 120 against the socket board 101.

In some embodiments, more than one target contact pins 112a whose electrical characteristics are desired during the testing process are included within the contact pins 112. In this case, each of the target contact pin 112a is coupled with a signaling route extending between a device contact pad and a socket board pad 102 within the socket board 101. The signaling routes are used for receiving and applying different test signals to the electronic device during the testing of the electronic device. In addition, more than one test traces 125 are formed on the calibration board 120, and each of the test traces 125 extends between a test pad 122 and a connection pad 113. Accordingly, each of the more than one connection pads 113 is aligned with one of the more than one target contact pins 112a, respectively, as illustrated in FIG. 1B. Here, it should be noted that only one test trace 125 is shown in FIG. 1B, and other test traces 125 are omitted for simplicity. When the apparatus is operating in the calibration mode, a measurement of the electrical characteristic may be carried out between one of the test pads 122 and one of the socket board pads 102, respectively. The measurement may be carried out individually for each pair of the test pad 122 and the socket board pad 102, to generate multiple measurement results for the test traces 125, the target contact pins 112a and the signaling routes. The measurement results can be used for calibrating a test result of the electronic device which may be obtained in a later step, as will be described below.

After the electrical characteristic has been measured, the calibration board 120 can be removed from the lower socket unit 110 and the upper socket unit 130. An electronic device to be tested can be mounted on the upper socket unit 130. Additionally, a device socket lid is introduced to assemble the electronic device, the lower socket unit 110 and the upper socket unit 130 together, so as to test the electronic device using the apparatus.

FIG. 1D illustrates a sectional view of the apparatus operating under the test mode to perform the testing step of an electronic device. In addition to the socket board 101, the lower socket unit 110 and the upper socket unit 130 which can also be used for the calibration mode as shown in FIGS. 1A to 1C, the apparatus further includes a device socket lid 170 which can be used for performing testing of the electronic device.

As shown in FIG. 1D, after the calibration board 120 is removed from the lower socket unit 110 and the upper socket unit 130, a guide plate 150 having a same thickness as that of the calibration board 120 is disposed between the lower socket unit 110 and the upper socket unit 130 to replace the calibration board 120 and serve as a placeholder. For example, the guide plate 150 may have a layout of a rectangular ring which is similar to the layout of the upper socket unit 130. In some embodiments, the apparatus further includes an interlayer 151 disposed on the plurality of fixing pins 123 and adjacent to an inner surface of the upper socket unit 130. Additionally, in some embodiments, an inner plate 152 may be arranged on the lower socket unit 110 and accommodated within the cavity of the upper socket unit 130. As such, the interlayer 151 may fill in a gap between the upper socket unit 130 and the inner plate 152, which also helps to position and secure the inner plate 152. In some other embodiments, the fixing pins 123 may have a sufficient height to secure the inner plate 152, where the interlayer 151 may be omitted. Particularly, the inner plate 152 may include a platform and a sidewall around the platform, which is used for accommodating the electronic device 160. Top portions of the contact pins 112 may be exposed from the inner plate 152, and the inner plate 152 may include a plurality of through holes to receive the contact pins 112, respectively. The top portions of the contact pins 112 may be exposed from the inner plate 152 for connection with the electronic device 160 under test.

The electronic device 160 is mounted within the cavity of the upper socket unit 130, or particularly, on the inner plate 152 for fixation. The electronic device 160 may include various types of electronic modules, such as a Radio Frequency (RF) device, a semiconductor chip, a resistor, a capacitor, a System in Package (SiP) module or other large-sized devices with complex functionalities. The electronic module included within the electronic device 160 may be encapsulated by a mold cap. Moreover, the electronic device 160 has a plurality of conductive pads at its bottom surface to provide an electrical connection between the electronic device 160 and the contact pins 112 of the lower socket unit 110. To be more specific, each of the conductive pads can be aligned with one of the contact pins 112.

The device socket lid 170 can be used for pressing the electronic device 160 against the socket board 101. To be more specific, a portion of the device socket lid 170 is inserted into the cavity of the upper socket unit 130 and placed onto the electronic device 160. During a testing process of the electronic device 160, an external force can be applied onto the device socket lid 170 and then be transferred to the electronic device 160, thereby the electronic device 160 may press the contact pins 112, including the target contact pin(s) 112a and the non-target contact pin(s) 112b against the socket board 101 to set up an elastic electrical connection between the electronic device 160 and the socket board 101. In some embodiments, the device socket lid 170 is constructed to have a shape that can be in contact with a top surface of the electronic device 160, a top surface of the inner plate 152 and a top surface of the upper socket unit 130 at the same time. As such, a distance at which the electronic device 160 is pressed towards the socket board 101 can be limited since the movement of the device socket lid 170 may be prevented when at least a portion of the device socket lid 170 is in contact with the upper socket unit 130 and/ the inner plate 152. In some embodiments, the inner plate 152 may be a floating plate which can be moved vertically relative to the lower socket unit 110. The floating plate 152 may also be pressed against the socket board 101 by the device socket lid 170 such that the electronic device 160 accommodated within the floating plate 152 may also be pressed towards the socket board 101.

In this way, a test result is generated by testing the electronic device 160 through the signaling route of the socket board 101. Then the test result is calibrated according to the measurement result associated with the testing path 126 (as illustrated in FIG. 1C), which is generated using the calibration board 120 (as shown in FIGS. 1A to 1C) before the testing process. Since the calibration board 120 with the test trace 125 provides a reliable and stable connection from the target contact pin 112a to the external measurement equipment, a convenient and accurate measurement of the electrical characteristic can be carried out. This generates accurate calibration information, such as the path loss within the apparatus. Thus, the accuracy of the test result of the electronic device 160 may be greatly improved when the test result is calibrated according to the accurate calibration information. In addition, referring back to FIGS. 1A to 1C, the socket board 101, the lower socket unit 110 and the upper socket unit 130 used for generating the calibration information are exactly the same as those used for testing the electronic device 160 in FIG. 1D. Thereby, the calibration information is generated in a measurement environment which mimics the testing environment used for testing the electronic device 160. Furthermore, when the path loss is measured, the contact pins 112 are coupled with the socket board 101 which is used during the testing step of the electronic device 160. Thus, the path loss is measured by taking into account the mismatching of a heterojunction effect between the contact pins 112 and the socket board 101 during the actual testing step of the electronic device 160, which also contributes to the accurate calibration of the test result.

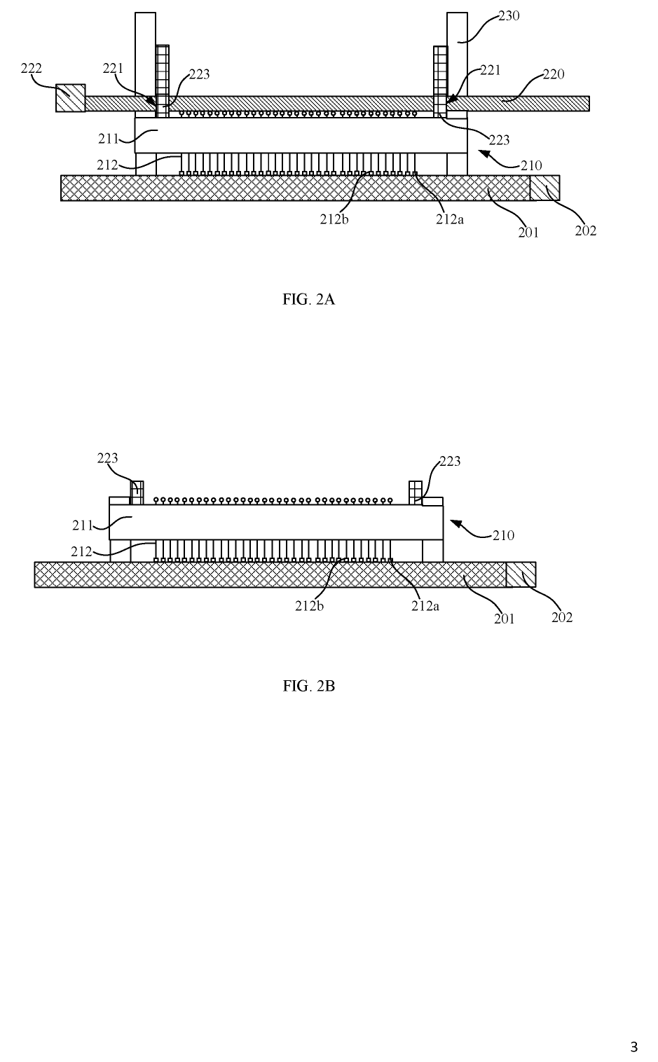

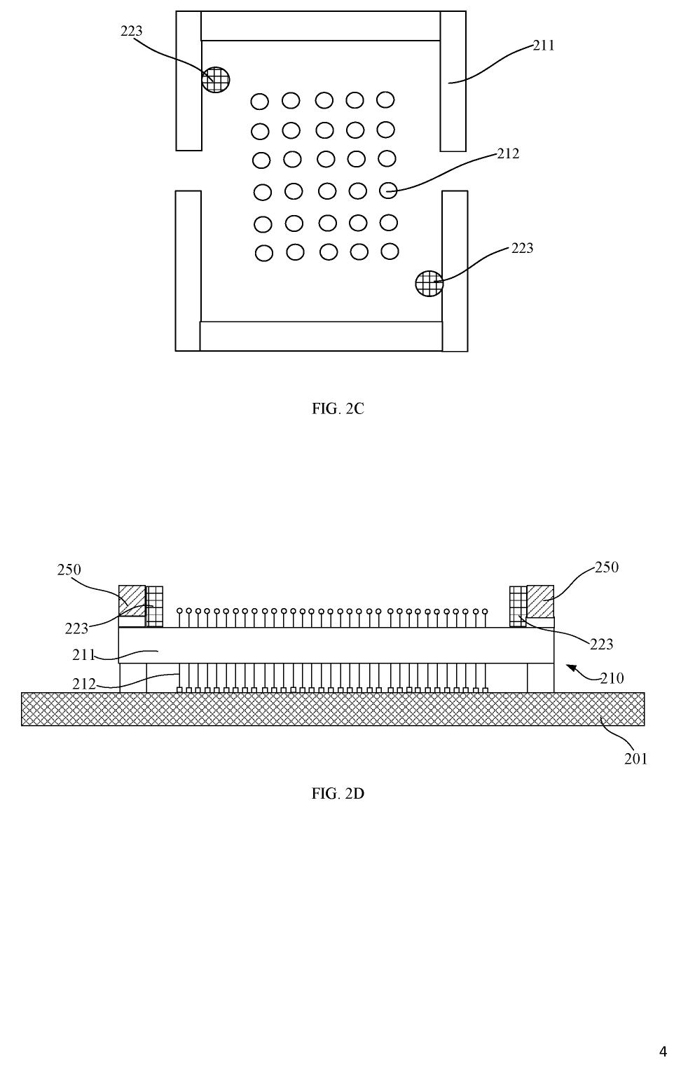

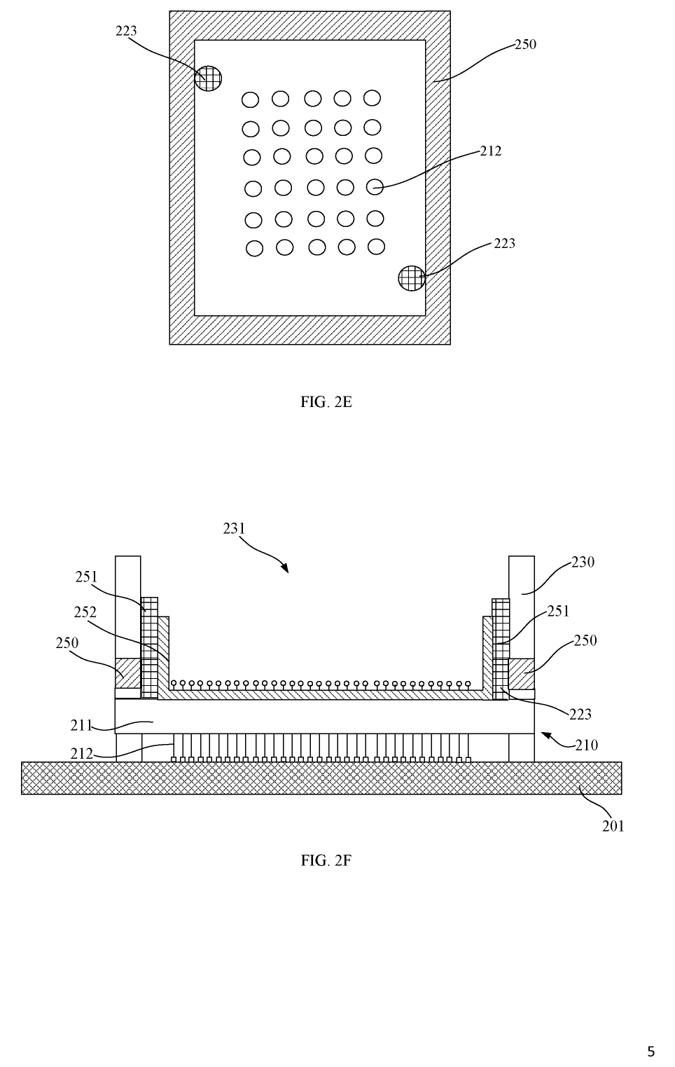

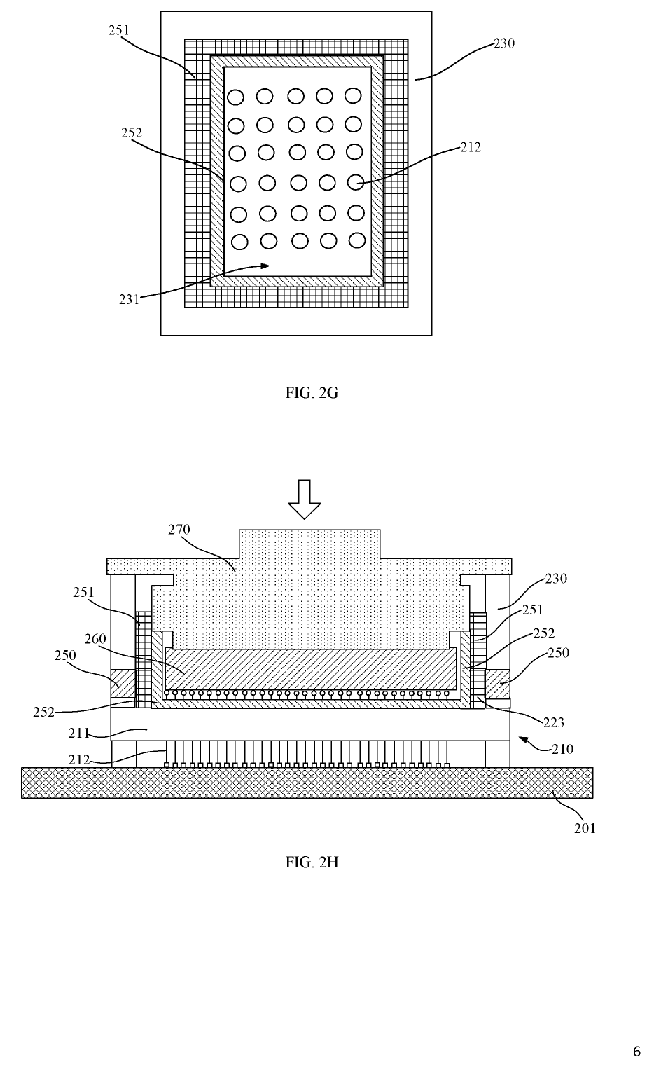

FIGS. 2A to 2H illustrate various steps of a method for testing an electronic device according to a second embodiment of the present application. In some embodiments, the method can be implemented by the apparatus shown in FIGS. 1A to 1D.

FIG. 2A illustrates a calibration step during the method. In particular, FIG. 2A shows a sectional view of a part of the apparatus when it is operating in a calibration mode.

As shown in FIG. 2A, a socket board 201, a lower socket unit 210, an upper socket unit 230 and a calibration board 220 are provided. The socket board 201 has a device placement region, a test region, and a signaling route each extending between a device contact pad in the device placement region and a socket board pad 202 in the test region. The lower socket unit 210 includes a lower socket body 211, and a plurality of contact pins 212 vertically extending through the lower socket body 211 and movable vertically relative to the lower socket body 211. The contact pins 212 include a target contact pin 212a and at least one non-target contact pin 212b. In some embodiments, the contact pins 212 may be pogo pins. The lower socket unit 210 is disposed onto the device placement region of the socket board 201, such that the device contact pad is aligned with the target contact pin 212a. Additionally, the socket board 201 may include at least one additional device contact pad in the device placement region which is aligned with the at least one non-target contact pin 212b.

Next, a calibration board 220 having a test trace 225 extending between a test pad 222 and a connection pad is provided. The calibration board 220 is mounted onto the lower socket unit 210 such that the connection pad is aligned with the target contact pin 212a. As such, the connection pad is electrically connected with the target contact pin 212a, and the target contact pin 212a is electrically connected with the device contact pad and the signaling route within the socket board 201. This forms a testing path between the test pad 222 and the socket board pad 202 which are electrically coupled with each other.

In some embodiments, the lower socket unit 210 further includes a plurality of fixing pins 223 on its top surface, and the calibration board 220 further includes a plurality of through holes 221. When the calibration board 220 is mounted onto the lower socket unit 210, the plurality of fixing pins 223 are aligned with the plurality of through holes 221 respectively, and the calibration board 220 is moved towards the lower socket unit 210 to insert the fixing pins 223 into the through holes 221, respectively. Next, an upper socket unit 230 with a cavity is mounted onto the calibration board 220 to secure the calibration board 220 between the lower socket unit 210 and the upper socket unit 230.

Next, a measurement result is generated by measuring an electrical characteristic associated with the testing path between the test pad 222 and the socket board pad 202 through the target contact pin 212a. In some embodiments, each of the test pad 222 and the socket board pad 202 may be respectively coupled with a VNA (Vector Network Analyzer) port of measuring equipment for generating the measurement result. The electrical characteristic may be a path loss within the test apparatus including the contact pins 212 and the socket board 201.

Next, as shown in FIG. 2B, the calibration board 220 and the upper socket unit 230 are removed from the lower socket unit 210. FIG. 2C illustrates a top view of the lower socket unit 210 including the lower socket body 211, the contact pins 212 and the fixing pins 223 in FIG. 2B.

Next, the apparatus may be changed to a test mode after an assembling process, which will be elaborated below.

As shown in FIG. 2D, a guide plate 250 having a same thickness as that of the calibration board 220 is mounted on the lower socket unit 210, which replaces the calibration board 220. For example, the guide plate 250 may have a layout of a rectangular ring, which is aligned with a peripheral portion of the lower socket unit 210. A top view of the guide plate 250 mounted on the lower socket unit 210 is illustrated in FIG. 2E.

Next, as shown in FIG. 2F, an interlayer 251 is disposed onto the plurality of fixing pins 223. In some embodiments, the interlayer 251 may also have a layout of a rectangular ring. In some embodiment, the number of the fixing pins 223 may be two, which are arranged near two opposite corners of the guide plate 250 to provide a balanced mechanical support to the interlayer 251 mounted thereon. It can be appreciated that the number of the fixing pins 223 may be three, four or even more to support the calibration board 220 in a more uniform and balanced manner. Next, the upper socket unit 230 is mounted onto the guide plate 250, which is adjacent to an outer surface of the interlayer 251. Next, an inner plate 252 is disposed onto a top surface of the lower socket unit 210 and arranged within the cavity 231 of the upper socket unit 230.

Particularly, the inner plate 252 may include a platform and a sidewall around the platform, which is used for accommodating an electronic device under test in a subsequent step. Top portions of the contact pins 212 may be exposed from the inner plate 252, where the inner plate 252 may include a plurality of through holes to receive the contact pins 212. A top view of the contact pins 212 of the lower socket unit 210, the interlayer 251, the upper socket unit 230, and the inner plate 252 are illustrated in FIG. 2G. As shown in FIGS. 2F and 2G, the interlayer 251, the upper socket unit 230, and the sidewall of the inner plate 252 may have a similar layout of a rectangular ring but have different sizes, and the contact pins 212 may be arranged in a central region of the rectangular rings, which are used for connection with the electronic device under test. In addition, in some embodiments, the interlayer 251 may fill the gap between the upper socket unit 230 and the inner plate 252, which helps to position and secure the inner plate 252 in place. It can also be appreciated that the interlayer 251 may be omitted in some alternative embodiments.

In this way, the apparatus is easily changed between the calibration mode and the test mode with the same socket board 201, the lower socket unit 210 and the upper socket unit 230 after the assembling process.

Next, as shown in FIG. 2H, an electronic device 260 is mounted onto the inner plate 252. The electronic device 260 has a set of conductive pads at its bottom surface to provide an electrical connection between the electronic device 260 and the contact pins 212 of the lower socket unit 210. To be more specific, each of the conductive pads are aligned with one of the contact pins 212, respectively.

Next, a device socket lid 270 is disposed above the electronic device 260 and at least partially inserted into the cavity 231 of the upper socket unit 230, to press the electronic device 260 against the socket board 201. Thus, the contact pins 212, including the at least one non-target contact pin 212b and the target contact pin 212a are pressed against the socket board 201 via the electronic device 260, thereby setting up an electrical connection between the electronic device 260 and the socket board 201 through the contact pins 212.

Next, a test result is generated by testing the electronic device 260 through the signaling route of the socket board 201. Then the test result is calibrated according to the measurement result, which is generated using the calibration board 220 (as shown in FIG. 2A) before the testing step, thereby improving the accuracy of the test result.

The details of the apparatus used for testing the electronic device 260 may be similar to those illustrated with respect to the apparatus shown in FIGS. 1A to 1D, which will not be elaborated in detail here for simplicity.

While the exemplary apparatus and method for testing an electronic device of the present application is described in conjunction with corresponding figures, it will be understood by those skilled in the art that modifications and adaptations to the apparatus and method may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. An apparatus for testing an electronic device, wherein the apparatus comprises:
a socket board having a device placement region, a test region, and a signaling route extending between a device contact pad in the device placement region and a socket board pad in the test region;
a lower socket unit mounted on the device placement region, wherein the lower socket unit comprises a lower socket body, and a plurality of contact pins vertically extending through the lower socket body and movable vertically relative to the lower socket body, and wherein the plurality of contact pins comprises a target contact pin aligned with the device contact pad;
a calibration board removably mounted on the lower socket unit, wherein the calibration board comprises a test trace extending between a test pad and a connection pad electrically connectable with the target contact pin when the calibration board is mounted on the lower socket unit, such that a measurement result is generated by measuring an electrical characteristic associated with a testing path between the test pad and the socket board pad which are electrically coupled with each other through the target contact pin; and
an upper socket unit mounted on the lower socket unit, and for securing the calibration board with the lower socket unit.

2. The apparatus of claim 1, wherein the lower socket unit is further configured to, when the calibration board is removed from the lower socket unit, hold the electronic device and electrically couple the electronic device with the socket board; and wherein the apparatus further comprises:
a test module for testing the electronic device through the socket board when the electronic device is held on the lower socket and electrically coupled with the socket board, wherein the test module is further configured to calibrate a test result of the electronic device according to the measurement result associated with the testing path.

3. The apparatus of claim 1, wherein the plurality of contact pins comprise pogo pins.

4. The apparatus of claim 1, wherein the lower socket unit further comprises a plurality of fixing pins protruding from its top surface, and the calibration board further comprises a plurality of through holes for receiving the plurality of fixing pins respectively when the calibration board is mounted on the lower socket unit.

5. The apparatus of claim 4, wherein the fixing pins are arranged on a periphery of the lower socket unit.

6. The apparatus of claim 1, wherein the socket board comprises a plurality of signaling routes, and the signaling route is one of the plurality of signaling routes.

7. An apparatus for testing an electronic device, wherein the apparatus is operable between a test mode and a calibration mode, and the apparatus comprises:
a socket board having a device placement region, a test region, and a signaling route extending between a device contact pad in the device placement region and a socket board pad in the test region;
a lower socket unit mounted on the device placement region, wherein the lower socket unit comprises a lower socket body and a plurality of contact pins vertically extending through the lower socket body and movable vertically relative to the lower socket body, and the plurality of contact pins comprise a target contact pin aligned with the device contact pad;
an upper socket unit operably mounted on the lower socket unit and having a cavity for accommodating the electronic device;
a calibration board removably mounted between the lower socket unit and the upper socket unit when the apparatus is operating in the calibration mode, wherein the calibration board comprises a test trace extending between a test pad and a connection pad electrically connectable with the target contact pin when the calibration board is mounted on the lower socket unit, such that a measurement result is generated by measuring an electrical characteristic associated with a testing path between the test pad and the socket board pad which are electrically coupled with each other through the target contact pin; and
a device socket lid removably mounted on the upper socket unit and insertable into the cavity of the upper socket unit and on the electronic device when the apparatus is operating in the test mode, and for pressing the plurality of contact pins against the socket board via the electronic device when the apparatus is operating in the test mode, such that the electronic device is electrically connected with the socket board through the contact pins and the electronic device is testable via the signaling route of the socket board.

8. The apparatus of claim 7, further comprising:
a test module for testing the electronic device through the socket board when the apparatus is operating in the test mode, wherein the test module is further configured to calibrate a test result of the electronic device according to the measurement result associated with the testing path.

9. The apparatus of claim 7, wherein the lower socket unit further comprises a plurality of fixing pins protruding from its top surface, and the calibration board further comprises a plurality of through holes for receiving the plurality of fixing pins respectively when the calibration board is mounted on the lower socket unit.

10. The apparatus of claim 9, further comprising:
an interlayer operably disposed onto the plurality of fixing pins.

11. The apparatus of claim 7, further comprising:
an inner plate operably disposed on the lower socket unit and accommodated within the cavity of the upper socket unit, wherein the inner plate is configured for receiving the electronic device when the apparatus is operating in the test mode.

12. The apparatus of claim 7, further comprising:
a guide plate having a same thickness with that of the calibration board, and operably disposed between the lower socket unit and the upper socket unit when the apparatus is operating in the test mode.

13. A method for testing an electronic device using a test apparatus, wherein the test apparatus comprises: a socket board having a device placement region, a test region, and a signaling route extending between a device contact pad in the device placement region and a socket board pad in the test region; and wherein the method comprises:
mounting a lower socket unit having a lower socket body and a plurality of contact pins vertically extending through the lower socket body and movable vertically relative to the lower socket body onto the device placement region of the socket board, to align a target contact pin of the plurality of contact pins with the device contact pad;
mounting a calibration board having a test trace extending between a test pad and a connection pad onto the lower socket unit, to electrically connect the connection pad with the target contact pin;
disposing an upper socket unit having a cavity onto the calibration board to fix the calibration board on the lower socket unit;
generating a measurement result by measuring an electrical characteristic associated with the testing path between the test pad and the socket board pad which are electrically coupled with each other through the target contact pin;
removing the calibration board from the lower socket unit and the upper socket unit;
mounting the electronic device within the cavity of the upper socket unit to align a plurality of conductive pads of the electronic device with the plurality of contact pins, respectively;
placing a device socket lid on the upper socket unit to insert a portion of the device socket lid into the cavity of the upper socket unit and onto the electronic device, to press the plurality of contact pins against the socket board via the electronic device and set up an electrical connection between the electronic device and the socket board through the contact pins; and
testing the electronic device and calibrating a test result of the electronic device according to the measurement result of the electrical characteristic.

14. The method of claim 13, wherein the lower socket unit further comprises a plurality of fixing pins on its top surface, and the calibration board further comprises a plurality of through holes, wherein mounting the calibration board having a test trace extending between a test pad and a connection pad onto the lower socket unit comprises:
aligning the plurality of fixing pins with the plurality of through holes respectively and move the calibration board towards the lower socket unit to mount the calibration board onto the lower socket unit.

15. The method of claim 13, wherein after removing the calibration board from the lower socket unit and the upper socket unit and before mounting the electronic device within the cavity of the upper socket unit, the method further comprises:
disposing a guide plate having a same thickness with that of the calibration board on the lower socket unit;
disposing an interlayer onto the plurality of fixing pins;
mounting the upper socket unit onto the guide plate; and
disposing an inner plate onto the lower socket unit and within the cavity of the upper socket unit; and
mounting the electronic device within the cavity of the upper socket unit further comprises:
mounting the electronic device onto the inner plate.
